(19) United States
(12) Patent Application Publication
(10) Pub. No.: US 2009/0289362 A1
(43) Pub. Date: Nov. 26, 2009

(54) Low Inductance Ball Grid Array Device Having Chip Bumps on Substrate Vias

(75) Inventors: Kenneth R. Rhyner, Rockwall, TX (US); Peter R. Harper, Lucas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/124,292

(22) Filed: May 21, 2008

(51) Int. Cl. H01L 23/498; H01L 21/60

(52) U.S. Cl. 257/738; 438/125; 257/E23.069; 257/E21.511

(57) ABSTRACT

A high-frequency BGA device (500) with the chip (501) assembled by metal bumps (503) on an insulating substrate (502) with conductive vias (505) and metal traces (504). Chip bumps which serve the high frequency signal terminals are attached directly to the lands (510) on the vias in order to minimize parasitic electrical parameters such as inductance, resistance, and IR drops, thus achieving the required 0.1 nH inductance for each chip terminal. Chip bumps which serve the remaining chip terminals are attached to pads on certain substrate traces. In both cases, the bumps can be attached reliably because the lands on the vias and the pads on the traces are plated with additional metal layers (511, 512), which provide extra thickness as well as a metallurgically suitable surface.

### FIELD OF THE INVENTION

The present invention is related in general to the field of semiconductor devices and processes, and more specifically to the structure and electrical characteristics of ball grid array packages suitable for high-speed electrical devices.

### DESCRIPTION OF RELATED ART

In the popular ball-grid-array (BGA) packages of electronic devices, the semiconductor chip is assembled on an insulating substrate, typically in the central region. The substrate has at least one metal layer, usually a thin copper foil, which is patterned into lands, such as contact pads, and interconnecting traces. Electrically conductive through-holes (so-called vias) extend through the substrate thickness to connect the lands on one surface to solder pads on the opposite surface, where solder balls are attached in order to handle the connection to external parts. Solder balls have, for practical reasons, relatively large diameters; consequently, when a device requires a great number of balls, the placement of the balls may necessitate substrates of an area considerably larger than the chip area.

Traditionally, the chips are adhesively attached to the substrate and electrically connected to the traces by bonding wires. An example of such wire bond assembly can be found in the well-known microStar package used in hand-held wireless telephones. In later years, BGA packages have experienced a transition to flip-chip mounting of the chips onto the substrates. For this assembly, the semiconductor chips have their contact pads provided with solder bumps. In the assembly process, the chip is flipped to face the substrate and the solder bumps are re-melted to connect to the substrate pads. These pads, of course, have to have a metallurgical configuration to be wetted by liquid solder. As an example, pads made of copper usually need a flash of gold to be reliably solderable. For chips with high numbers of input/output (I/O), the flip-chip assembly with solder bumps has clear technical advantages over the traditional wire bond assembly.

For chips with a small area yet a high number of I/O's, the shrinking of solder bumps runs into practical limits (handling, melting, wetting etc.); it is thus advantageous to replace the reflow solder with a non-reflow metal such as gold or copper. The non-reflow bumps are assembled on bump pads on the substrate. It is common practice to assemble these high I/O chips in the central substrate region and distribute the conductive vias to the opposite surface in the peripheral substrate regions. Conductive traces are, therefore, required to connect the bump pads in the central region with the vias in the peripheral regions.

The trend to shrink device areas has driven the need to combine the bump pads with the traces, or better still, to assemble the bumps directly on the traces. Since the assembly is a thermo-compressive attachment, the thin metal foil has to be locally strengthened for the thermo-compressive bump attachment. The strengthening is best accomplished by locally depositing additional metal onto the foil, most economically performed by an electroplating technique. The plating process simultaneously provides a metallurgical surface suitable for gold or copper attachment. For the plating technique, the substrate traces connecting the bump pads and the vias serve the double purpose as connectors to a plating bar, which is hooked up to the plating bath; the technique is described in the U.S. patent application No. 11/947,310, filed on Nov. 29, 2007, by Rhyner et al., “Extended Plating Trace in Flip Chip Solder Mask Window”.

An example of a BGA with plated traces is shown in FIG. 1. The figure shows a portion 100 of a ball grid array (BGA) device, which includes a semiconductor chip 101 assembled on a substrate 102. The figure emphasizes the connections for signals (non-common net assignments). The chip inputs/outputs (I/O's) have contacts with metal bumps 103, preferably gold or copper; the bumps connect the chip contacts to the contact pads 103a on the substrate.

Substrate 102 has metal-filled, electrically conductive vias 105. Solder balls 106, attached to the metal-filled vias, provide connection to external parts. The filler metal of each via is capped with a land 110. FIG. 1 shows of the metal traces, which extend from the contact pads 103a, only the trace portion 104. The traces connect the pads 103a to the plating bar for the additional plating. It may be mentioned that for stress relief, the gap between chip 101 and substrate 102 may be filled with a polymerized polymer precursor 107. Further, chip 101 and metal traces 104 are frequently protected by an encapsulating compound 108, which also provides mechanical strength to the BGA; frequently, encapsulation 108 is a molding compound.

FIG. 2 depicts, in top view, a pair of metallic lands 201 over through-holes 202 (dashed). A trace 203a connects each land to the bump pad 208. The bump pad, in turn is connected by trace 203b to the plating bar (arrows 210). The surface of the substrate, including the traces and the lands, is covered by an insulating layer (so-called soldermask, assumed to be transparent in FIG. 2). A window 206 in the soldermask permits the plating of metal layers onto trace portion 207 during the plating operation.

FIG. 3 depicts, in cross sectional view, a certain pad and trace configuration of a portion of FIG. 1 at a different scale. Sheet-like insulating substrate 301 has on its surface 301a the metal foil (preferably copper) patterned into land 303a, located over through-hole 302, and trace 303b. Trace 303b connects land 303a to the plating bar 310. Insulating soldermask 304 is shielding trace 303b except for a window 305.

The plating process, preferably electroplating, adds metal into windows 302 and 305, preferably up to the thickness of the soldermask. In some devices, a nickel coat is deposited on the copper, and then a gold coat is deposited on the nickel; in other devices, a coat of copper is plated before the nickel coat is deposited. FIG. 8 depicts coat 307 in window 305. The plating process further adds a metal coat 309 on the copper foil exposed in the through-hole 302. In the reflow process of solder body 330 (preferably including tin), solder is wetting readily on the gold surface of coat 309 and thus fills the remainder of through-hole 309, thereby transforming it into a conductive via. Solder body 330 provides the connection to external parts.

FIG. 3 shows semiconductor chip 320 with contact 321 and metal bump 322. For the assembly on the substrate, bump 322 is preferably made of gold or copper, which attach readily to the gold surface of coat 307. An electrical path is thus established for signals between chip contact 321, solder body 330 and external parts. In FIG. 3, the electrical path is indicated by arrows 340.

The endeavour, however, to apply the flip-chip assembly on substrates to high-frequency BGA devices is running into severe problems. For example, in the Digital Radio Processor (DRP) device families, the network of traces interconnecting the bumps on the traces, the vias, and the plating bar creates an unacceptable deterioration in electrical parameters. The inductance from the chip contact pad to the package termination (at the substrate solder ball) turns out to be about an order of magnitude too high; similarly, the resistance is increased by about an order of magnitude; and parasitics such as trace-to-trace capacitance and trace-to-trace coupling are introduced. In addition, in many devices is an increasing shortage of real estate for the layout of the interconnecting traces; the solution to use substrates with more than one metal layer is cost prohibitive.

### SUMMARY OF THE INVENTION

Advanced high-frequency semiconductor devices require parasitic inductance, capacitance, and resistance values of their terminals about an order of magnitude smaller than today's best Ball Grid Array (BGA) packages can offer. Applicants conducted a detailed analysis of the contribution each component of the semiconductor flip-chip, the BGA package and its one-metal layered substrate adds to the electrical parasitics.

Applicants discovered that the parasitics can be minimized by eliminating the metallic traces between the chip terminals and the package termination, and placing chip bumps directly on the substrate lands of the conductive vias. Trace-to-trace inductive coupling and capacitance are thus eliminated, and trace resistance and IR drops are reduced. In addition, the elimination of traces gains design space, improves the package routability, and even allows in some devices to reduce the number of routing metal layers.

One embodiment of the invention is a high-frequency BGA device with the chip assembled by metal bumps on an insulating substrate with conductive vias and metal traces. Chip bumps which serve the high frequency signal terminals are attached directly to the lands on the vias in order to minimize parasitic electrical parameters such as inductance, resistance, and IR drops, thus achieving the required 0.1 nH inductance for each chip terminal. Chip bumps which serve the remaining chip terminals are attached to pads on certain substrate traces. In both cases, the bumps can be attached reliably because the lands on the vias and the pads on the traces are plated with additional metal layers, which provide extra thickness as well as a metallurgically suitable surface.

As an example, while the traces are made of copper between 6 and 20 μm thick, the lands and pads have additional coats of copper, nickel, and outermost gold for a total thickness between 20 and 45 μm. The noble surface insures a metallurgical affinity to the chip bumps, which are preferably made of gold.

Since in most high-frequency BGA's the chip is assembled in the central region of the one-metal-layered substrate, the sites of a two-dimensional array under the chip area become usable as conductive vias for signals, when the sites can be routed for plating additional metal on the sites. The plating process disposes concurrently coats of bondable and solderable metals on exposed lands over the vias, on exposed portions of the traces, and in the vias. The plated lands and trace portions can then be used as bump sites for flipping a bumped chip onto the substrate, and the plated through-holes can be used for filling the vias and attaching solder balls to the substrate.

It is a technical advantage of the invention that of the traditional three signal interconnect structures from bumped chip terminal to package termination, namely bump pad, trace, and via (metal-filled through-hole topped by land), two structures are eliminated: bump pad and trace. This simplification eliminates trace-to-trace coupling and trace-to-trace capacitance, and reduces bump-to-via current path inductance from about 0.7 nH/mm to less than 0.1 nH/mm. It also reduces electrical impedance, and thus IR drop, for high frequency operation.

It is another technical advantage of the invention, that valuable real estate of the substrate area under the chip is freed up to be available for improved package routability, especially trace layout. In some devices, this savings avoids the need of requiring an additional routing layer—a significant cost savings.

As an additional technical advantage of the invention, the methodology is scalable. The approach of attaching the bumps of the high-frequency chip terminals directly on the substrate via can be used for more than one bump on a via, and it can also be extended to multi-layer substrates. This means that the electrical and cost advantages can be retained for several future fabrication nodes and product generations.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 shows a schematic cross section of a portion of a ball grid array (BGA) device with a flip chip mounted on a one-metal layer substrate having metal-filled vias and solder balls in known technology.

FIG. 2 is a schematic top view of a couple of via lands, with traces connecting the lands to bump pads and the plating bar in known technology.

FIG. 3 depicts a schematic cross section of a detail of FIG. 1, illustrating a chip portion flip-connected to a trace leading to a via with solder ball.

FIG. 4 is a schematic cross section of a chip bump directly attached to the land over a conductive via through an insulating substrate, according to an embodiment of the invention.

FIG. 5 illustrates a schematic cross section of a portion of a ball grid array device according to the invention, the bumped chip flipped onto the via lands of a one-metal layer substrate having solder balls under the peripheral and the central substrate regions; the via lands have additional metals according to the invention.

FIG. 6 is a schematic cross section of a chip bump directly attached to the land over a conductive via through an insulating substrate, according to another embodiment of the invention.

FIG. 7 shows a schematic top view of a couple of via lands with a bump attached to each land according to the invention; traces connect the lands to the plating bar.

FIG. 8 is a schematic cross section of a plurality of chip bumps directly attached to the land over a conductive via through an insulating substrate, according to another embodiment of the invention.

FIG. 9 shows a schematic top view of a couple of via lands with a plurality of bumps attached to each land; traces connect the lands to the plating bar.

### DETAILED DESCRIPTION OF THE PREFERRED EMBODIMENTS

The present invention is a continuation of U.S. patent application No. ______, filed on ______ Apr., 2008 (Rhyner et al., “BGA with One-Metal-Layer Substrate having Traces for Plating Pads under the Chip”).

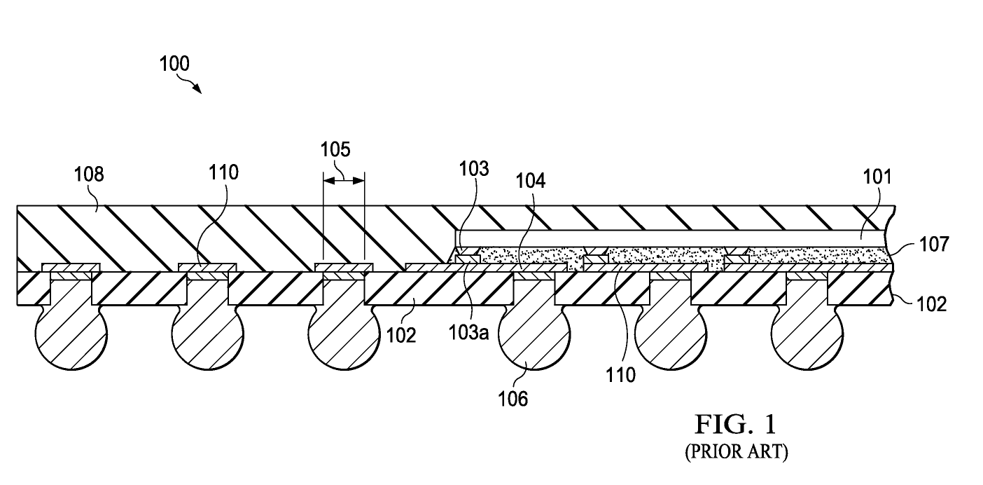

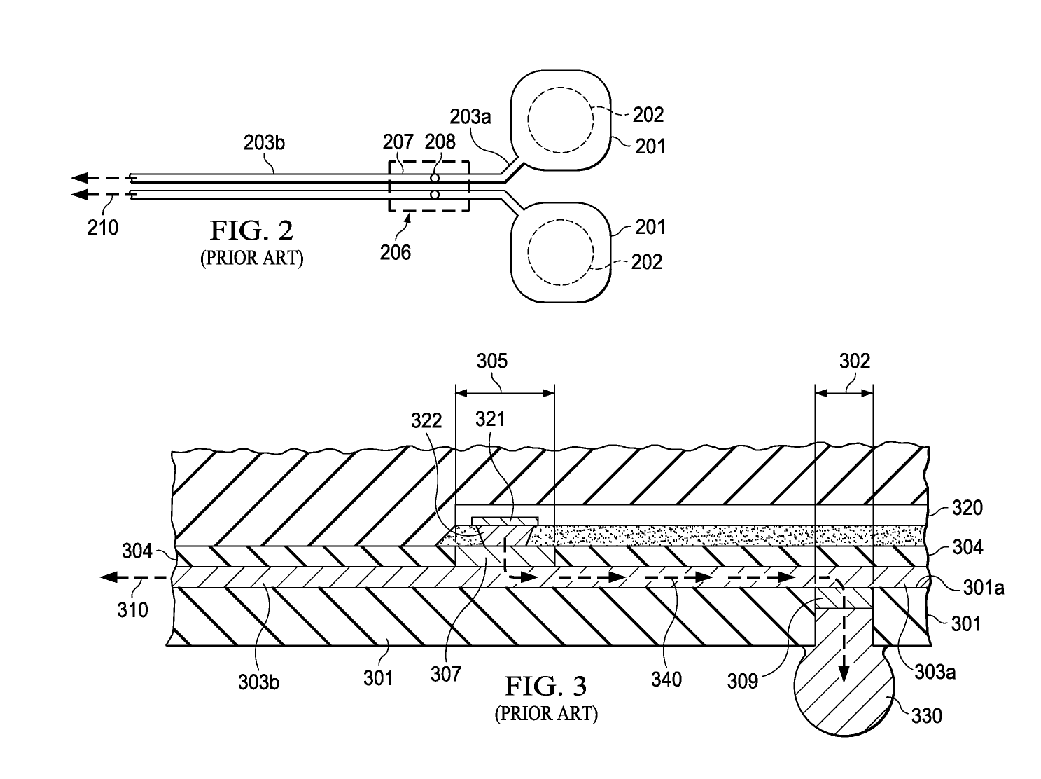

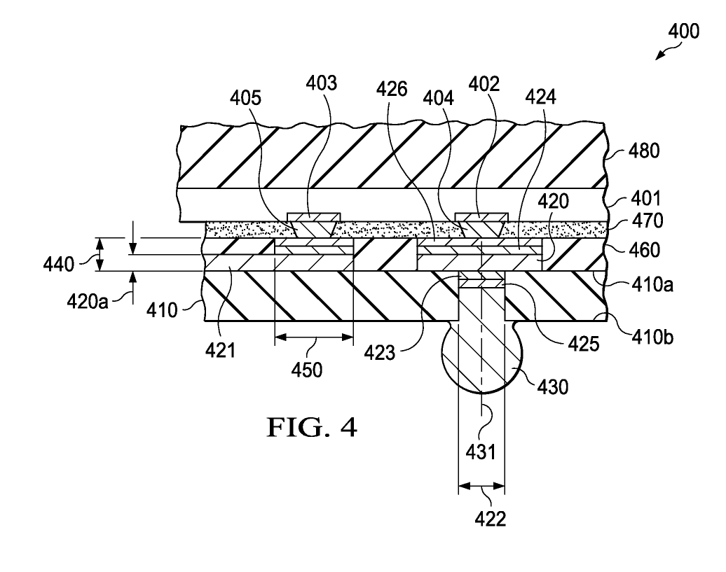

FIG. 4 illustrates an embodiment of the invention. FIG. 4 depicts a portion of an electronic device with a ball grid array (BGA) package, generally designated 400, which includes a semiconductor chip 401 with a first set of terminals 402 and a second set of terminals 403. In specific embodiments, chip 401 is an integrated circuit for Digital Radio Processor (DRP) devices, and the first set terminals 402 are high-frequency terminals. The second set terminals 403 serve low frequency signal inputs/outputs (I/O's), which have non-common net assignments. Chip 401 has additional terminals for power and ground, which have common net assignments and are not illustrated in FIG. 1. The chip terminals are preferably made of copper with a surface of gold or aluminum. Attached to the chip terminals are metal bumps, preferably made of gold or copper, which connect the chip terminals to the substrate. The bumps on terminals 402 are designated 404, the bumps on terminals 403 are designated 405.

Chip 401 is assembled on a substrate 410. The substrate is preferably made of a sheet-like insulating material such as a tape of polyimide compound or a related polymer. The preferred thickness range is between about 50 and 300 μm. Substrate 410 has a first surface 410a and a second surface 410b. On first surface 410a are patterned metal layers; layers 420 are lands over through-holes, and layers 421 are traces. Layers 420 and 421 are portions of a metal foil, which has been laminated on substrate 410 (process see below) and patterned; the foil is preferably made of copper or a copper alloy in the thickness range between about 6 and 20 μm.

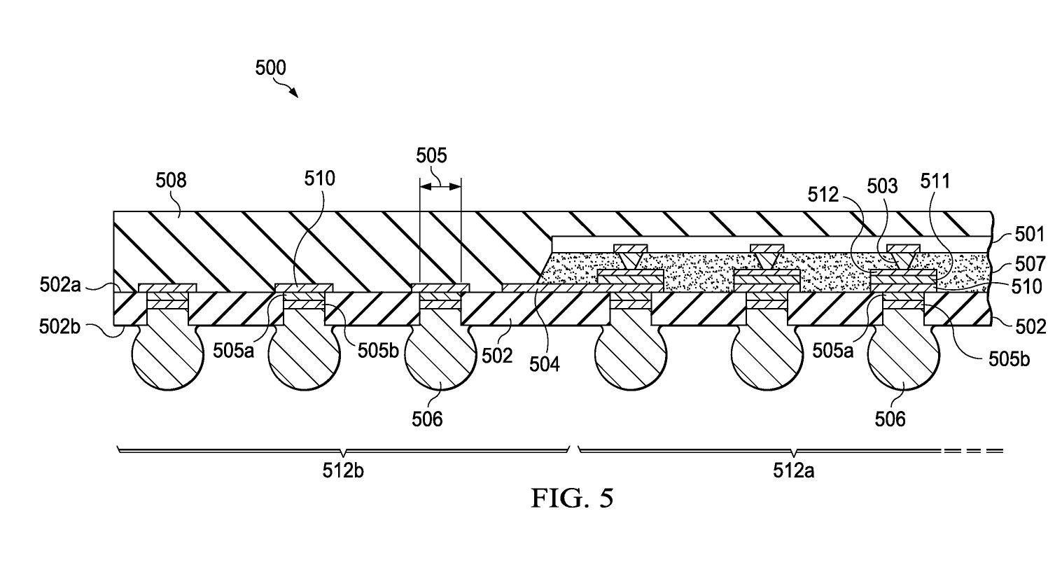

Substrate 410 has metal-filled through-holes 422, which extend from the first surface 410a to the second surface 410b. Where the through-holes intersect with the substrate surfaces, they form a surface contour, which is preferably a circle or a square. The through-holes are disposed in locations matching the first set terminals of chip 401 and form a first plurality of through-holes (for the second plurality of through-holes see FIG. 5). As FIG. 4 illustrates, the substrate has solder bodies 430 on the second surface 410b, which also fill a portion of the through-holes and are attached to the other metals in the through-hole.

These other metals in the through-holes are detailed in FIG. 4. As mentioned, metal land 420 is a copper foil, which stretches across through-hole 422. Land 420 has a thickness 420a preferably in the range from 6 to 20 μm. Land 420 has contours larger than the surface contours of through-hole 422; it thus overlaps the through-hole, at least slightly, and closes it off. In contact with land 420 is metal layer 423, which has the diameter of the through-hole and is preferably made of nickel with a thickness from about 1 to 5 μm. Layer 424, in contact with land 420 on the land surface opposite through-hole 422, is also made of nickel and has the same thickness as layer 423, since it is fabricated by the same plating process (see below); layer 424 has the dimensions of land 420.

In contact with layer 423 is metal layer 425, which also has the diameter of the through-hole and is made of a solderable metal, preferably of a noble metal such as gold, with a thickness from about 2 to 3 μm. Layer 426, in contact with layer 424, has the dimensions of layer 424 and land 420, and is made of a metal with affinity to the chip metal bumps 404. Preferably, layer 426 is made of a noble metal such as gold about 2 to 3 μm thick. When layer 426 and layer 425 are fabricated in the same plating process (see below), they are made of the same solderable and bondable metal with the same thickness. The sum of the layer thicknesses over the first plurality through-holes 422 is designated 440 in FIG. 4; it is referred to as first metal thickness. If the thickness 420a of layer 420 is referred to as the second layer thickness, it is evident from FIG. 4 that the first thickness 440 is greater than the second thickness 420a.

In most devices, the metal layers 423 and 425 fill through-hole 422 only partially. The remaining portion of the through-hole is filled with solder of the solder body 430. When completely filled with metal, as shown in FIG. 4, through-hole 422 is commonly referred to as a conductive via.

As stated, the first set terminals 402, each with a bumps 404, are the high-frequency terminals of chip 401. As FIG. 4 illustrates, the first set bumps 404 are directly and without trace in contact with and attached to the matching bondable land of the first plurality vias. According to the invention, bump 404 is positioned on land layer 426 so that the distance from chip terminal 402 to the solder body 430 is a minimum. As an example, bump 404 may be centered on layer 426, as indicated in FIG. 4 by symmetry line 431. In this manner, the electrical resistance and the inductance of the bump-to-via current path become a minimum; for instance, the inductance becomes less than 0.1 nH.

As FIG. 4 illustrates, substrate 410 further has metallic traces 421 of the second thickness 420a, which connect each land 420 to an edge of the substrate in order to allow the hook-up to a metal plating bath during the fabrication process. (see below). As shown in FIG. 4, selected traces have pads of width 450 on certain locations of the traces. The pads have the same sequence of metal layers as lands 420 and are thus exhibit the first thickness and a surface affinity to the chip metal bumps. The pads are disposed in locations matching the second set bumps (the bumps 405 on the second set terminals 403 for low frequency signal I/O's and non-common net assignments). FIG. 4 shows that the second set chip bumps 405 are in contact with and attached to the matching trace pads 450.

The device portion as depicted in FIG. 4 further includes the insulating solder mask 460, in which the windows are defined for lands 420 and trace pads 45o; the insulating polymer precursor 470, which is a polymerized compound filling any space between the assembled chip and the soldermask and reducing stress on the bump joints; and protective polymer compound 480, which encapsulates the assembled chip (and the substrate surface, see FIG. 5) and provides robustness to the device.

As an embodiment of the invention, FIG. 5 illustrates a portion 500 of a ball grid array (BGA) device, which includes a semiconductor chip 501 assembled on a substrate 502. The figure emphasizes the connections for signals (non-common net assignments). The chip signal inputs/outputs (I/O's) represent the first set of terminals; they have contacts with metal bumps 503, preferably gold or copper. The bumps connect the chip contacts to the contact pads on the substrate. For clarity reasons, the second set of chip terminals for common net assignments (power, ground) is not shown in FIG. 5.

Substrate 502 is made of a sheet-like insulating material, preferably a tape of a polyimide compound or alternatively of a thicker and stiffer polymer. Sheet-like substrate 502 has a first surface 502a and a second surface 502b. The substrate includes a central region 512a, onto which the chip is attached, surrounded by peripheral regions 512b, which border on the substrate edges. Substrate 502 has a metal foil on the first surface 502a; the metal foil is preferably made of copper and is patterned. Portions of the patterned foil include the lands 510 over the through-holes of the substrate; consequently, the lands are made of the same metal as the foil, preferably copper.

Substrate 502 has through-holes 505, which extend from the first surface 502a to the second surface 502b and have a surface contour at the intersection with the first surface 502a. FIG. 5 shows that device 500 has a first plurality of through-holes in the central region 512a, where the through-holes match the first set chip terminals, and a second plurality of through-holes in the peripheral regions.

Through-holes 505 are filled with metal so that they are electrically conductive vias. Each through-hole 505 includes a layer 505a, contiguous with land 510; layer 505a is preferably made of nickel. Attached to layer 505a is layer 505b, which is preferably made of a noble metal such as gold. Solder balls 506, attached to the metal-filled vias, provide connection to external parts. The vias in the peripheral regions 512b of the substrate feature the lands capping off each via as the copper layer mentioned above.

On the other hand, the vias in the central region 512a of the substrate have the layered structure of the lands, which is described in detail in FIG. 4 according to the invention. Referring now to FIG. 5, on top of each land 510 capping a via in the central region is a layer 511, which is preferably made of nickel. Since the layer 511 is fabricated in the same plating process (see below) as layer 505a, it has the same thickness; however, layer 511 has the contour of land 510, larger than the contour of layer 505a. In contact with layer 511 is layer 512 made of a noble metal, preferably gold. It has the same contour as land 510.

Of the traces patterned from the metal foil on substrate surface 502a and extending from the signal lands 510 to the substrate edge, FIG. 5 shows only the trace portion 504. As FIG. 5 further depicts, the gap between chip 501 and substrate 502 may be filled with a polymerized polymer precursor 507 for stress relief. Further, chip 501 and metal traces 504 are frequently protected by an encapsulating compound 508, which also provides mechanical strength to the BGA, especially when insulating substrate 502 is made of a thin tape. Preferably, encapsulation 508 is a molding compound.

As FIG. 5 demonstrates, the thickness of the substrate contact pads over the vias in the central region 512a, being the sum of the layer thicknesses for layers 512, 511, and 510, is greater than the thickness of the land over the vias in the peripheral region 512b. Further, the pads have, by virtue of layer 512, a surface affinity to the chip metal bumps 503, and match the locations of the bumps. Consequently, the chip bumps can be attached to the substrate and the first plurality vias so that the electrical resistance and inductance are minimized; for instance, the inductance becomes less than 0.1 nH.

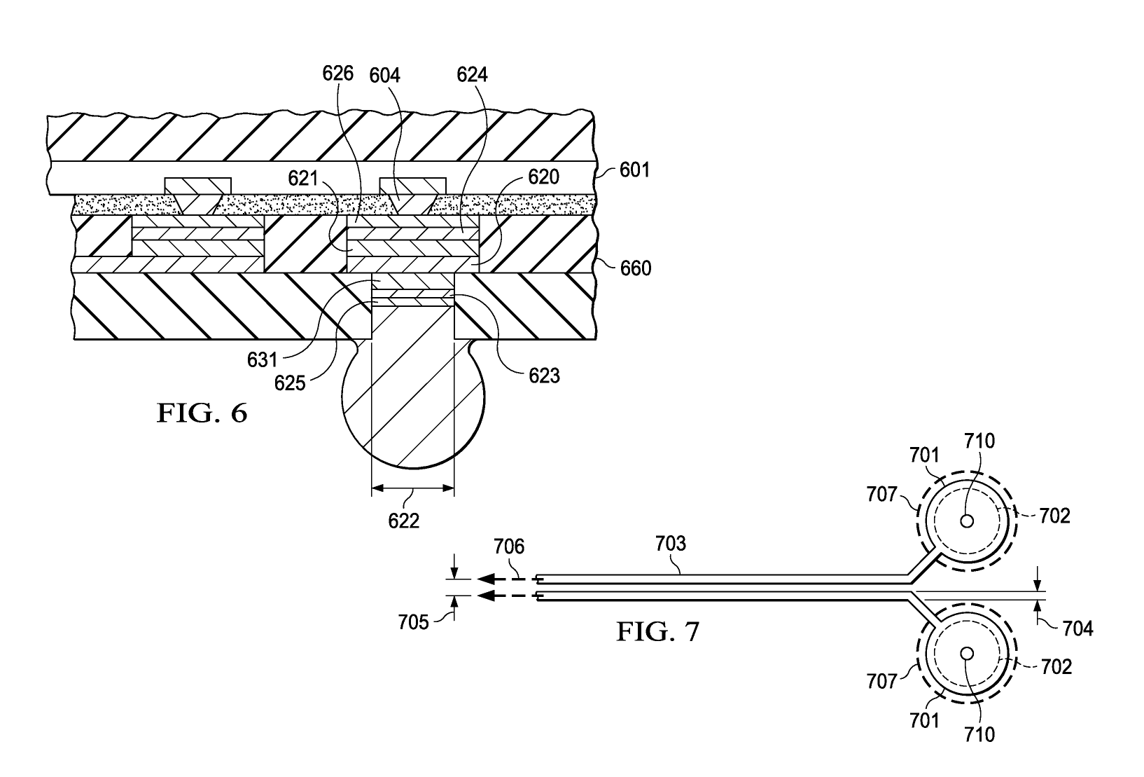

A variation of the bump-on-via structure of FIG. 4 is shown in the embodiment of FIG. 6. According to the invention, bumps 604 of chip 601 are attached directly to the land 620 over metal-filled through-hole 622; the bumps are preferably gold, but may alternatively comprise copper. The robustness of the lands 620 over the vias 622 (more specific: the lands over the first plurality vias in the central substrate region) is enhanced by adding an additional layer 621 onto land 620. Land 621 is preferably made of copper. The thickness of layer 621 may be in the same range 6 to 20 μm as the thickness of layer 620, but for some devices may be considerably thicker or thinner, as the assembly conditions of the bumps requires.

Layer 621 is preferably deposited on layer 620 by a plating technique. The contours of layer 621 are determined by the contours of the opening in soldermask 660. When electroplating is used, another layer 631 of equal thickness is simultaneously deposited on the land surface facing through-hole 622. Layer 631 has the diameter of the through-hole 522 and contributes to fill the through-hole with metal.

The other metal layers on land 620 and inside through-hole 622 are analogous to the layers depicted in FIG. 4. In contact with layer 631 is metal layer 623, which has the diameter of the through-hole and is preferably made of nickel with a thickness from about 1 to 5 μm. Layer 624, in contact with layer 621 is also made of nickel and has the same thickness as layer 623, since it is fabricated by the same plating process (see below); layer 624 has the dimensions of layer 621.

In contact with layer 623 is metal layer 625, which also has the diameter of the through-hole and is made of a solderable metal, preferably of a noble metal such as gold, with a thickness from about 2 to 3 μm. Layer 626, in contact with layer 624, has the dimensions of layer 624, layer 621, and land 420, and is made of a metal with affinity to the chip metal bumps 604. Preferably, layer 626 is made of a noble metal such as gold about 2 to 3 μm thick. When layer 626 and layer 625 are fabricated in the same plating process (see below), they are made of the same solderable and bondable metal with the same thickness.

As stated earlier, the benefit of connecting traces to the plating bar is the ability to deposit metal coats in the through-holes and on the lands over the through-holes intended to become bump pads. FIG. 7 depicts, in top view, a pair of metallic lands 701 over through-holes 702 (dashed). A trace 703 connects each land to the plating bar (indicated by arrows 706). The trace width 704 may be between about 10 and 20 μm, and the pitch 705 center-to-center between adjacent traces between about 15 and 25 μm; the industry trend is for both ranges to decrease. The surface of the substrate including the traces, but excluding the lands, is covered by an insulating layer (so-called soldermask, assumed to be transparent in FIG. 7). During the plating operation, metal coats are deposited from underneath onto the land exposed within the through-hole, at least partially filling the though-hole with metal to become a conductive via.

In addition, metal coats are deposited on top of lands 701, because a window 707 around each land had been opened in the insulating soldermask for the plating operation. The land exposed by the window permits deposition of metal coats during the plating operation so that the exposed land becomes suitable for attaching a contact bump 710 (about 10 to 20 μm diameter) affixed to the chip-to-be-assembled.

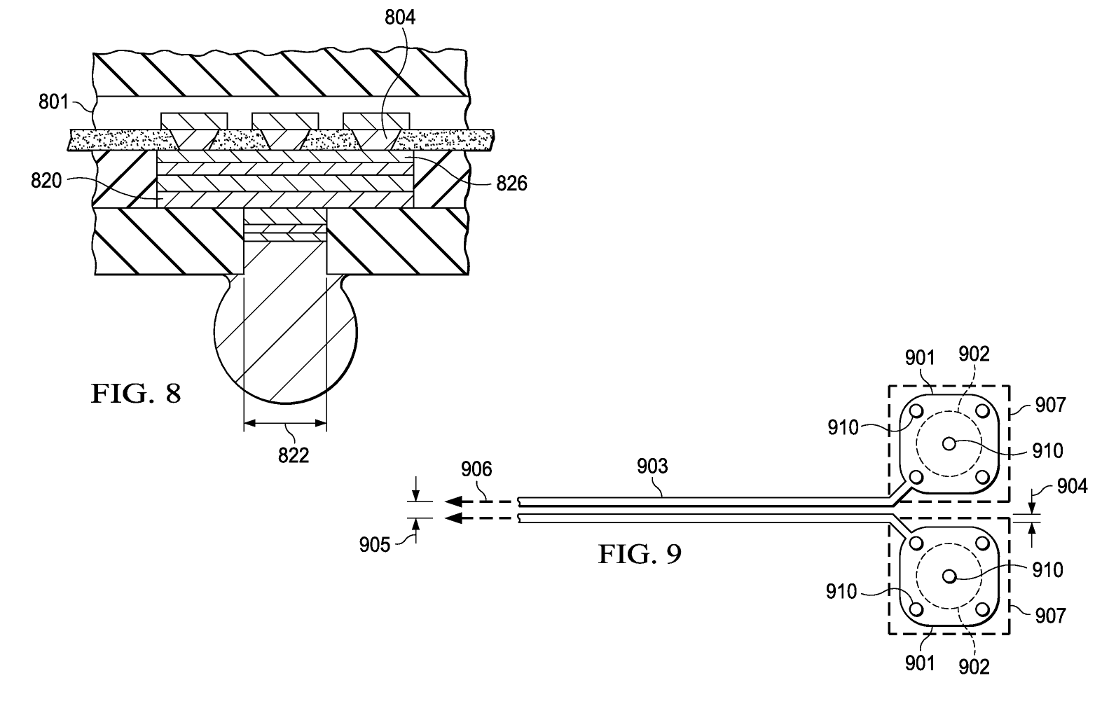

FIG. 8 depicts another embodiment of the invention. A through-hole 822 closed off by land 820 has the same sequence of metal layers inside the hole and on top of the land as in FIG. 6. More than one bump 804, attached to high-frequency terminals of chip 801, are in contact with the top plated layer 826 of the land. This arrangement allows more than one high-frequency terminal of the chip to have a connection to the package termination at an inductance of less than 0.1 nH.

FIG. 9 illustrates such multi-terminal arrangement in top view, with 5 bumps attached to one metal-filled via. A pair of metallic lands 901 are placed over through-holes 902 (dashed). The lands have substantially the contours of squares. A trace 903 connects each land to the plating bar (indicated by arrows 906). As in the arrangement of FIG. 7, the trace width 904 may be between about 10 and 20 μm, and the pitch 905 center-to-center between adjacent traces between about 15 and 25 μm; the industry trend is for both ranges to decrease. The surface of the substrate including the traces, but excluding the lands, is covered by an insulating layer (so-called soldermask, assumed to be transparent in FIG. 9). During the plating operation, metal coats are deposited from underneath onto the land exposed within the through-hole, at least partially filling the though-hole with metal to become a conductive via.

In addition, metal coats are deposited on top of lands 901, because a window 907 around each land had been opened in the insulating soldermask for the plating operation. The land exposed by the window permits deposition of metal coats during the plating operation so that the exposed land becomes suitable for attaching the contact bumps 910 (about 10 to 20 μm diameter) affixed to the chip-to-be-assembled. Needless to say, he number of five bumps 910 is only exemplary.

Another embodiment of the invention is a method for fabricating an electronic device, especially a device of the ball grid array type for high frequency operation. An insulating substrate is provided, which may be, for example, a polyimide tape about 50 to 300 μm thick. The substrate has a first and a second surface, a periphery, and a central region surrounded by peripheral regions.

In the next process step, through-holes are opened in the substrate by techniques such as laser drilling, mechanical drilling, or etching. The through-holes extend from the first to the second surface. A first plurality of the through-holes spreads throughout the central substrate region, and a second plurality of through-holes spreads throughout the peripheral substrate regions.

In the next step, a metal foil is deposited on the first surface, for instance by a lamination process. The foil may be made of copper or a copper alloy in the thickness range from about 6 to 18 μm; the foil covers the through-holes. The metal foil is patterned by laying a photoresist pattern on the foil, protecting portion of the foil while the exposed metal portions are stripped by etching; thereafter, the photoresist is removed. The pattern thus created is an interconnected network of metal lands and traces. Preferably, the traces have a width between about 10 and 20 μm, and, wherever they run in parallel, a pitch center-to-center between about 15 and 25 μm.

The metal network is designed so that the lands are located over the through-holes of the first and the second plurality, and the traces connect each land to the substrate periphery for connection to the plating bar during the plating process.

Next, an insulator mask, customarily called a solder mask, is disposed over the first surface and the patterned foil of the substrate. Then, a semiconductor chip is provided, preferably a chip for high frequency operation. The chip has a first and a second set of terminals; the first set is in locations of the first plurality of through-holes. On all terminals are metal bumps, preferably gold bumps, for assembling the chip by a flip-chip technique.

Next, windows are opened in the mask; the windows are located in the central substrate region and positioned to expose the lands over the first through-hole plurality and further portions of the traces, which match the second chip terminal locations.

Using a metal deposition process, preferably the electroplating technique, coats of bondable and solderable metals are deposited on the lands and the trace portions exposed in the solder mask windows, as well as on the metal foil portions exposed inside the through-holes. By this deposition step, the exposed lands and trace portions are prepared to become bump pads, and the through-holes are transformed to become conductive vias. In the preferred deposition process, first a nickel coat of about 1 μm thickness is plated on the metal foil (which is preferably copper), and then a gold coat of about 2 to 3 μm thickness is plated on the nickel coat.

In an optional deposition step, a copper coat may first be deposited on the exposed metal foil (preferably copper) in the preferred thickness range of 10 to 20 μm, before the nickel plating is performed. This copper coat adds some strengthening layer to the lands and traces, and in the through-holes.

In the next process step, the semiconductor chip is assembled on the substrate by attaching the chip bumps to the bump pads. Preferably, this attaching step involves gold-to-gold interdiffusion. As a result of the chip attachment, the first chip terminals are positioned over the lands on the vias in the first plurality of through-holes; the chip area is, therefore, positioned over the lands on the vias in the first plurality of through-holes (the central substrate region), providing the opportunity to use these vias under the chip area as signal connections in non-common net assignments.

Finally, solder bodies are attached to the vias on the second substrate surface; since this step involves the reflowing of the solder material, the vias are completely filled with metal, while a sizeable amount of solder material is still left for connections to external parts. A metallic short-path is thus created form the solder bodies to the chip terminals, resulting in minimum electrical resistance and inductance between the chip terminals and the package termination.

After the step of assembling the chip, an optional process step may be performed to enhance the reliability of the BGA device. In this step, any space between the assembled chip and the insulator mask is filled with a polymer precursor compound; frequently, such compound is called an underfill material, because the precursor is pulled into the space between chip and insulator mask by capillary forces. After the underfill step, the precursor is allowed to polymerize at elevated temperatures. The polymerized underfill material helps to reduce thermo-mechanical stress on the assembled bumps.

Another optional process step includes, after the underfill step, the step of encapsulating the substrate surface including the insulator mask and the assembled chip with a protective polymer compound. The preferred method is a molding technique using an epoxy-based, filler-enhanced compound. This step is followed by polymerizing (hardening) the compound at elevated temperatures. The encapsulated device is thus protected against environmental disturbances and mechanical damage.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to any type of semiconductor chip, discrete or integrated circuit, in a flip-chip BGA-type package. The material of the semiconductor chip may comprise silicon, silicon germanium, gallium arsenide, or any other semiconductor or compound material used in integrated circuit manufacturing.

As another example, the invention applies to BGA devices with substrates having more than one metal layer and thus more than one level of traces. As another example, the invention applies to BGA substrates with regularly pitched two-dimensional site array of lines and rows; it further applies to substrates with equal pitches of the array in the central region and in the peripheral regions, and it applies to substrates with different pitches of the array in the central region and in the peripheral regions.

An another example, the invention applies to devices, which have contours of the lands over the vias only slightly larger than the surface contours of the vias, as well as to devices, which have contours of the lands over the vias markedly larger than the surface contours of the vias.

It is therefore intended that the appended claims encompass any such modifications or embodiments.

We claim:

1. An electronic device comprising:
a semiconductor chip having metal bumps on a first and a second set of terminals;
an insulating substrate including a central region surrounded by peripheral regions, the substrate having edges, a first and a second surface, and metal-filled through-holes extending from the first to the second surface, the through-holes having a surface contour;
a first plurality of through-holes being in the central region, matching the first set terminals, and a second plurality of through-holes being in the peripheral regions;
the substrate further having metallic lands over the through-holes and in contact with the metal in the through-holes, the lands having contours larger than the through-hole surface contours;
the lands over the first plurality through-holes having a first metal thickness and a surface affinity to the chip metal bumps, the lands over the second plurality through-holes having a second thickness thinner than the first thickness;
the substrate further having metallic traces of the second thickness, the traces connecting each land to a substrate edge;
selected traces having pads in the central region, the pads having the first thickness and a surface affinity to the chip metal bumps, the pads matching the second set bumps; and
the first set chip bumps in contact with the matching lands over the first plurality through-holes, and the second set chip bumps in contact with the matching trace pads.

2. The device of claim 1 wherein the substrate further has solcer bodies on the second surface, the bodies attached to the metal in the through-holes.

3. The device of claim 1 wherein one bump of the first set terminals is positioned on, and in contact with, a land over a first plurality through-hole.

4. The device of claim 1 wherein more than one bump of the first set terminals are positioned on, and in contact with, a land over a first plurality through-hole.

5. The device of claim 2 wherein the first set chip bumps are in contact with the matching lands over the first plurality through-holes so that the distance from the chip terminal to the solder body is a minimum.

6. The device of claim 1 wherein the metallic bumps of the semiconductor chip are made of gold.

7. The device of claim 1 wherein the metallic bumps of the semiconductor chip are made of copper.

8. The device of claims 1 wherein the first metal thickness is in the range from about 18 to 45 μm, and includes a layer of copper on the first substrate surface, a coat of nickel on the copper, and a coat of a noble metal on the nickel.

9. The device of claim 1 wherein the second metal thickness is in the range from about 6 to 20 μm, and includes a layer of copper on the first substrate surface.

10. The device of claim 1 wherein the substrate edges provide connection to a plating bath.

11. A method for fabricating an electronic device comprising the steps of:
providing an insulating substrate having a first and a second surface, a periphery, and a central region surrounded by peripheral regions;
opening through-holes in the substrate, the through-holes extending from the first to the second surface, whereby a first plurality of through-holes spreads throughout the central region and a second plurality of through-holes spreads throughout the peripheral regions;
depositing a metal foil on the first surface, the foil covering the through-holes;
patterning the metal foil by forming lands and traces, the lands located over the through-holes of the first and the second plurality, and the traces connecting each land to the periphery;
disposing an insulator mask on the first surface and the patterned foil;
providing a semiconductor chip having metal bumps on a first and a second set of terminals, the first set in the locations of the first plurality of through-holes;
opening windows in the mask, the windows located in the central substrate region and positioned to expose the lands of the first through-hole plurality, and further to expose certain trace portions, which match the second set of chip terminal locations;
depositing coats of bondable and solderable metals on the exposed lands and trace portions, as well as in the through-holes, thereby preparing the exposed lands and trace portions to become bump pads and transforming the through-holes to become conductive vias;
assembling the chip on the substrate by attaching the chip bumps to the bump pads, whereby the first set chip terminals are positioned over the lands on the vias in the first plurality of through-holes; and
attaching solder bodies to the vias on the second substrate surface, thereby completely filling the vias to create a metallic short-path from the solder bodies to the chip terminals.

12. The method of claim 11 further including, after the step of assembling the chip, the step of filling any space between the assembled chip and the insulator mask with a polymer precursor compound, followed by the step of polymerizing the compound.

13. The method of claim 12 further including, after the step of filling any space, the step of encapsulating the substrate surface including the insulator mask and the assembled chip with a protective polymer compound, followed by the step of hardening the compound.

14. The method of claim 11 wherein the insulating substrate is a tape made of a polymer compound in the thickness range from about 50 to 300 μm.

15. The method of claim 11 wherein the metal foil is made of copper and has a thickness in the range from about 6 to 20 μm.

16. The method of claim 11 wherein the traces have a width between about 10 and 20 μm.

17. The method of claim 11 wherein the coats of metals include a nickel coat of about 1 μm thickness deposited on the copper, and a gold coat of about 2 to 3 μm thickness deposited on the nickel.

18. The method of claim 11 wherein the step of depositing metal is performed by electroplating.

19. The method of claim 11 further including, after the step of patterning the metal foil, the step of depositing a layer of copper, adding thickness to the exposed lands and traces, and in the through-holes.
